(19) United States
(12) Patent Application Publication
(10) Pub. No.: US 2015/0163902 A1
(43) Pub. Date: Jun. 11, 2015

(54) Z-AXIS INK AND APPLICATIONS THEREOF

(71) Applicant: T+Ink, Inc., Boston, MA (US)

(72) Inventors: Terrance Z. Kaiserman, Loxahatchee, FL (US); John Gentile, Montclair, NJ (US); Anthony Gentile, New York, NY (US)

(21) Appl. No.: 14/476,227

(22) Filed: Sep. 3, 2014

Related U.S. Application Data
(60) Provisional application No. 61/873,190, filed on Sep. 3, 2013.

(51) Int. Cl. H05K 1/09; H05K 1/02

(52) U.S. Cl. CPC H05K 1/092; H05K 1/0298; H05K 2201/09218

(57) ABSTRACT

An article of manufacture that includes a substrate having x, y and z-axes associated therewith, wherein the z-axis is perpendicular to the x and y-axes, and the x and y-axes are perpendicular to each other, and the z-axis being perpendicular to a plane formed by the surface of the substrate. The article preferably further includes a first layer of conductive ink having a first resistance applied to the surface of the substrate, a second layer of conductive ink having a second resistance applied to a portion of the first layer of the conductive ink, such that an interface layer having a resistance profile formed from a predetermined combination of the first and second resistance layer is formed between the first and second resistance layers, the interface layer having a resistance profile with values that vary along the z-xis.

### CROSS REFERENCE TO RELATED APPLICATIONS

The present application claims the benefit of the filing date of U.S. Provisional Patent Application No. 61/873,190 filed Sep. 3, 2013, the disclosure of which is hereby incorporated herein by reference.

### BACKGROUND/FIELD

The present application relates to conductive ink and related technologies; and in particular to a z-axis ink system that preferably includes a conductive pattern created using layers of conductive ink or traces that are printed on a support surface. More specifically, a z-axis matrix may be created by layering conductive ink traces having different conductivity/resistivity/impedance levels such that an interface is created between the different levels. The interface desirably forms another distinct layer that has a conductive level that is different from the two traces creating the interface. In this way, resistivity along the z-direction or z-axis of the ink trace changes so as to create a resistance signature.

### SUMMARY

An article of manufacture, comprising a substrate having x, y and z-axes associated therewith, wherein the z-axis is perpendicular to the x and y-axes, and the x and y-axes are perpendicular to each other; the z-axis being perpendicular to a plane formed by a surface of the substrate; a first layer of conductive ink having a first resistance applied to the surface of the substrate; a second layer of conductive ink having a second resistance applied to a portion of the first layer of the conductive ink; and an interface layer formed between the first layer and second layer, the interface layer having a resistance profile formed from a predetermined combination of the first and second resistance layers such that the resistance profile includes varying resistance values along the z-axis.

### BRIEF DESCRIPTION OF THE DRAWINGS

FIG. 1A illustratively depicts a portion of an article in accordance with an aspect of the present invention. FIG. 1B illustratively depicts a sensing zone in accordance with an aspect of the invention.

FIG. 2A illustratively depicts a sensing zone in accordance with an aspect of the invention. FIG. 2B illustratively depicts a plan view of a sensing zone in accordance with an aspect of the invention. FIG. 2C illustratively depicts sensing zones in accordance with an aspect of the invention. FIG. 2D illustratively depicts a credit card in accordance with an aspect of the invention.

FIG. 3 illustratively depicts a resistance topographically map in accordance with an aspect of the invention.

FIG. 4 illustratively shows a reader in accordance with an aspect of the invention.

FIG. 5 illustratively depicts a system in accordance with an aspect of the invention.

### DESCRIPTION

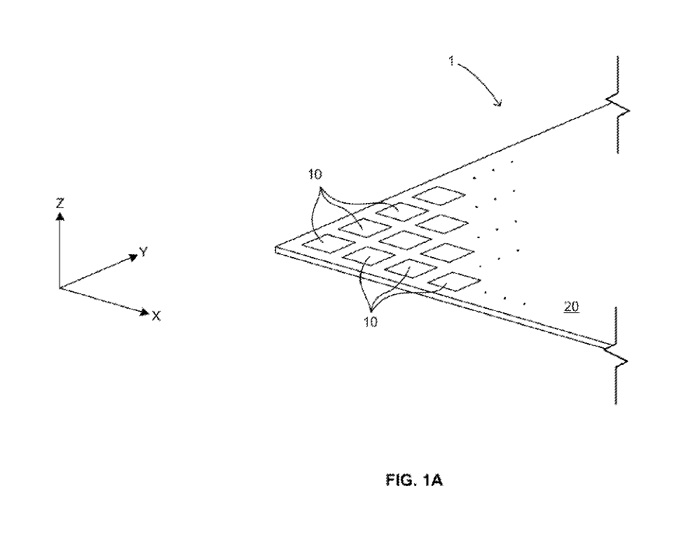

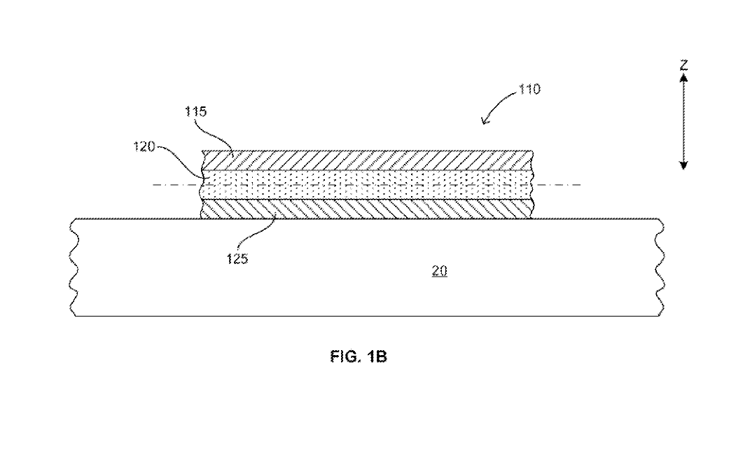

Turning now to FIG. 1A, there is illustratively depicted an article 1 having a plurality of resistive zones 10 in accordance with an aspect of the present invention. The zones 10 are shown in a grid-like pattern disposed on the substrate or surface 20 of the article 1 along the x and y direction. Though zones 10 are shown in a grid-like structure, they may be disposed in any pattern, including a more irregular pattern than is shown. The substrate or support surface 20 may comprise a film, credit card surface, paper, currency, plastic container or any other article of manufacture. In general, the substrate or support structure 20 is preferably a dielectric, or more generally may be made of any material that has conductivity that is different than the conductivity or resistance of zones 10. The conductivity of the substrate or support structure 20 is preferably chosen so that a reader is able to distinguish substrate 20 from the zones 10. This may be accomplished by having the conductivity of the substrate or support structure 20 lower than the conductivity of the sensing zones 10 by a factor that allows the substrate 20 to be distinguishable from the sensing zones 10. For example, the difference may be on an order of magnitude of five or greater. Functionally, as long as the difference between the zones 10 and the substrate or support surface 20 is sufficient to create a capacitive element, any substrate or support surface may suffice.

Turning now to FIG. 1B, there is shown an embodiment of one of the sensing zones 10 from FIG. 1A. As is shown in FIG. 1B, the sensing zone 110 is made up of layers 115, 120 and 125. As is also shown in FIG. 1B, the layers extend along the direction of the z-axis, which itself extends into or out of the plane of the substrate or support surface 20 in FIG. 1A. Layer 115 is preferably formed using a conductive ink. Layer 115 preferably has a resistance value r₁ or a conductivity ε₁. Layer 125 is preferably made of a second conductive trace formed using a conductive ink and has a second resistance r₂ or conductivity ε₂. As is shown in FIG. 1B, a third layer 120 is formed between layer 115 and layer 125. Further, layer 125 is depicted as formed on or being adhered in some fashion to the substrate 20. Thus, in the embodiment depicted in FIG. 1B, layer 115 would be the top or outer layer of the zone, whereas layer 125 would be the inner layer abutting the support surface 20.

In creating the zone 110, layer 125 would be first applied to the substrate 20 and layer 115 would then be applied to layer 125. Each layer may be applied as a conductive ink trace and may be formed using any known technology that lays out a trace on the substrate 20, including for example hot or cold foils, inkjet, offset, 3D, Screen Flexo, Gravure, slot die, lamination (both hot or cold). The top layer 115 would be then applied to layer 125. The interface between layers 115 and 125 is depicted as layer 120. More specifically, if layer 115 and layer 125 are chosen to have two different resistances, layer 120 would have a different resistance than those two layers, thereby providing an interface between layers 115 and 125. Thus, even though FIG. 1B shows layer 120 as being separate, in the preferred embodiment that layer is not formed by printing an ink or conductive trace having a third resistance. Rather, it is formed by the overlap or blending of the resistances between layers 115 and 125. As a specific example, consider two different inks having resistances of 10 kΩ carbon printed as layer 125 and a layer 115 printed using a 20 kΩ carbon. This selection of resistances preferably create an interface 120 having a resistance value of 15 kΩ where layers 115 and 125 blend together.

The inks that constitute layers 115 and 125 may be printed wet on wet, or wet on dry. Regardless of the way they are printed, they will have a different resistance where they interface. Either layer 125 or 115 preferably comprises an ink that is applied on to the surface of the substrate or support structure 20. These layers may comprise substantially conductive composition and they include any number of electrically conductive materials. Layers 115 and 125 preferably include between 1% to 100% (foils are 100% and so are precursor dry film weights) conductive material by weight. These layers may also include 0.1% or lower conductive material by weight using nano-tubes, nano wires or graphene. The desirable range depends upon the conductive material selected and on other ingredients in the system. A wide range of conductive materials may be used. It should be appreciated that the aforementioned ranges of conductivity/resistivity and the percentage of conductive materials in either layer is provided as an example of preferred ranges. Thus, conductivity/resistivity levels above or below the aforementioned ranges may be obtained while remaining within the scope of the present invention. In addition, the ranges of impedance between layers can be adjusted to allow for different resistance signatures.

The conductive materials are preferably consistent with desired additional properties of the substrate 20 on to which the zones are formed. Factors affecting the properties of the conductive materials include the flexibility and stretchability of the inks. For example, if the inks are being employed in an application such as on currency, which may be folded or bent into different shapes, it may be important to have stretchable inks. In contrast, if the inks are being applied to a flat sturdy surface such as a credit card, then stretchability may not be that important of a factor. In such circumstances, durability may be a more important factor.

The conductive materials that form layer 115 or 125 may be, but are not limited to, precious metals and non-precious metals such as base metal powders and flakes, inorganic powders coated with precious or base metals, graphite and elemental carbon powders, and various inorganic powders such as mica, TiO2, silica, etc., coated with antimony doped tin oxide. Such powders need not be spherical or flake-like. For example, silver coated fiberglass particles can be used. Suitable non-precious metals include iron, copper, brass, bronze, aluminum and nickel as well as non-precious metal coated non-conducting particles. Other suitable non-precious conductive materials include materials marketed by E.I. DuPont de Nemours under the trademarks ZELEC 1410M (antimony doped tin oxide on mica particles), and ZELEC 1610S (antimony doped tin oxide on silica particles) and GRAPHITE 850 from Asbury Graphite. Various conductive polymers, doped polyacetylene, doped polypyrrole, doped polyaniline and the like may also be used. It should be appreciated that other conductive materials besides those discussed herein may be used while remaining within the scope of the present invention.

Further in accordance with this aspect of the present invention, the conductive composition may preferably include at least 20-80% of silver in an embodiment and/or 10-40% of carbon in another embodiment. Alternatively, the conductive composition may also desirably include 10-40% of graphite in another embodiment. In addition, other conductors, including polymers, indium, single wall and multi-wall carbon nano-tubes and other nano-structures, as well as all other known conductors, in any color, composition, and shape and/or particle size may also be used.

Resins may also be used with the conductive materials. The resins that may be used may be any of the resins typically used for surface coatings. To this end, examples of suitable resins include acrylamide, acrylics, phenolics, bisphenol A type epoxy, shellac, carboxymethyl cellulose, cellulose acetate butyrate, cellulosics, chlorinated polyether, chlorinated rubber, epoxy ester, ethylene vinyl acetate copoloymers, maleics, melamine, natural resins, nitrocellulose solutions, isocyanates, hydrogenated resin, polyamide, polycarbonate, rosins, polyesters, polyethylene, polyolefins, polypropylene, polystyrene, polyurethane, polyvinyl acetate, silicone, vinyls, and water thinned resins. Additional suitable resins are described in the text entitled 1996 Paint Red Book, published by Modern Paint and Coatings Magazine, July 1995. Further, the resins may include any other materials which have suitable binding properties to bind the conductive materials and other ingredients of the second layer composition together.

The selected resins may be either water soluble or soluble in an organic solvent based system or may be 100% solids with no volatile fraction for example EB and UV curing inks and coatings. Alternatively, the resin may be dispersible in a suitable liquid, rather than truly soluble therein. A liquid dispersion medium may be used in which the resin is dispersed, but in which other materials may be truly dissolved. The resin may be used with or without cross-linking or a catalyst. If cross-linking is desired, it may be obtained by using a cross-linking agent or by application of heat to the composition or by choosing a self cross-linking resin. Functional conductors such as precursor inks may also be used that do not contain any resins or polymers.

As stated above, the resin may be dissolved or dispersed in various liquids which serve as the vehicle for carrying the resin. The ingredients of the particular vehicle are not critical to the present invention. Thus, layers 115 and 125 may be water based, or water miscible (including water dispersible), solvent based, plastisol based, UV, EB etc. Further, as also stated above, layers 115 and 125 may be applied as a bulk material system which does not require any solvents.

Additional details pertaining to the selection and constitution of materials that may form the layers 115 and 125 may be found by reference to U.S. Pat. No. 5,626,948 to Ferber et al., which is owned by the assignee of the present invention and which is incorporated by reference herein in its entirety. Further, U.S. Pat. No. 7,489,053 to Gentile, et al., which is owned by the assignee of the present invention and which is incorporated by reference herein in in its entirety, discloses additional information relating to the structure, selection and composition of materials that may form either conductive layer 115 or 125.

As reflected in FIG. 1B, and in relation to the above discussions, the resistance of layers 115, 120 and 125 will be different and may be selected so that they increase or decrease in either direction along the direction of the z-axis. In this way, the zones 10, or as depicted in more detail in FIG. 1B zone 110, create a resistive or conductive signature along the z-axis. By manipulating the conductive levels of layers 115 and 125, unique and different signatures may be created for a given zone. In this way, if each zone in a grid-like structure is given a unique signature that unique signature may then form a unique identifier across multiple zones which may be read by a reader. The reader will preferably comprise a device that is able to sense the resistance along the z-axis and into the object or substrate onto which the zones are printed or adhere to.

Further, by controlling access to the compositions that make up the inks, an additional level of uniqueness in the signatures may be created. For example, if layer 115 has a certain percentage of conductive materials, whereas layer 125 has a different percentage of conductive materials, the resulting interface 120 will thereby have its own unique overlapping conductive composition. In this way, the interface layer 120 denotes a unique z-axis signature, which may be used as a security measure. For example, by controlling the conductive composition level and process for applying the inks, the resistance profile of interface 120 may be designed to create a resistance profile. Such profiles may include parabolic, inverse parabolic, linear, or non-linear profiles when appropriately viewed along the z-axis. The profiles would then be used as unique codes for security, as identifiers or for other purposes. Thus, the unique resistance signature of the interface layer 120 (and in general all three layers 115, 120, 125) may be used for authentication purposes.

Moreover, although FIG. 1B shows a sensing zone with two layers (115, 125) and an interface (120), a multilayer structure may also be employed. In particular, instead of a single sensing zone, one could replicate the sensing zones 115, 120 and 125 by placing additional conductive layers atop layer 115. In this way, the signature along the z-axis could be made so that it shows a multilayer resistance signature. Further, by varying the levels of conductive composition, the resistance signature along the z-axis could be unique depending on the number of layers. That is, the signature could be coded in a way such that the different resistance values along the z-axis create a profile that serves as a unique signature. This provides the ability to create relatively sophisticated coding schemes that would be inherently more secure.

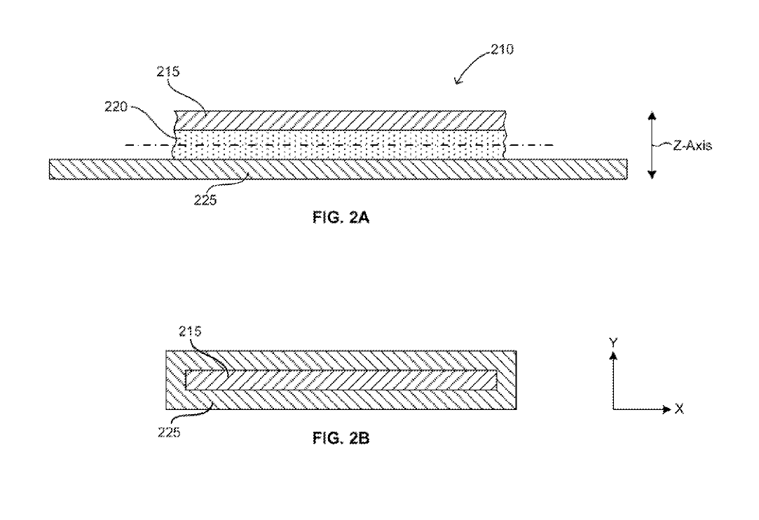

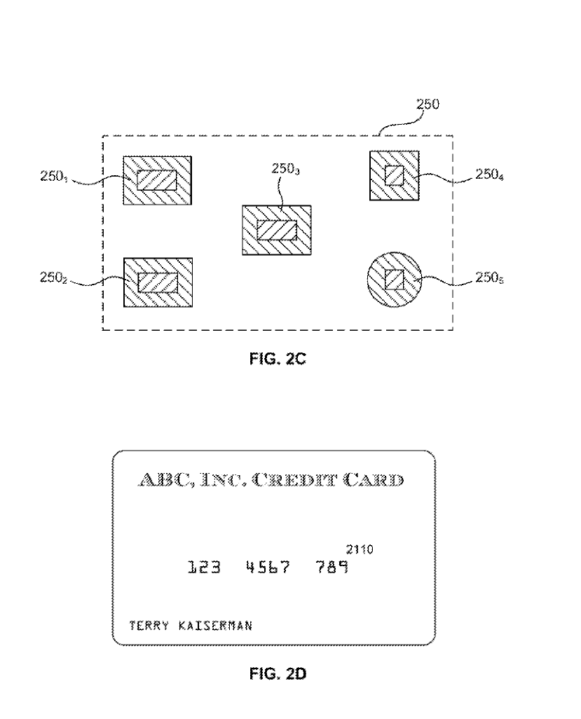

Turning now to FIG. 2A, there is shown an alternative embodiment of a sensing zone 210. In this embodiment, a first layer 215 is disposed opposite or atop a second layer 225. Between the two layers an interface layer 220 is created as described above. The layer 225 extends along the x and y direction such that there is not complete overlap between layer 215 and 225. As better seen in FIG. 2B, which is a plan view of FIG. 2A, layer 215 is surrounded by a rectangular box formed by layer 225. Thus, a reader looking along the z direction would see a region formed by 215, 220 and 225 in which the z-axis resistance has three different values. In contrast, there's also a region in which the z-axis resistance value has only the value of layer 225. This thus creates a unique foot print or sensing zone. A footprint provides another way of uniquely identifying a sensing zone. In that regard, although FIGS. 2A and 2B show a sensing zone with a rectangular footprint and one layer atop another as shown, various different footprints may be devised. For example, as shown in FIG. 2C, a sensing zone may take the shape of various discontinuous sub-sensing zones. In particular, FIG. 2C shows one such example in which the sensing zone 215 includes a number of sub-sensing zones 250₁ through 250₅. Each of the sub-sensing zones 250, include layers which provide a unique resistance signature along the z-axis. In addition, along the x and y direction, the different sub-sensing zone also provide another unique footprint with respect to the positioning and shape of the individual sub-sensing zones. In particular, as is shown, sub-sensing zone 250₅ is formed using a circle onto which a square is printed. In addition, the zones are arranged so that four are proximate a corner of the zone 250 with one relatively near the center. The placement, shape and z-axis resistance signatures of the sub-zones that make up the sensing zone, provide great flexibility in creating unique codes.

In addition, if as part of the manufacturing process the selection and composition of the inks can be maintained in confidence, it becomes almost impossible to be able to break the codes reflected by the sensing zones.

This makes this technology well-suited for applications where security is important. For example, each credit card is provided with a unique credit card number and, in addition, a user may also associate a pin code with a credit card. Present technology for putting both of these codes on a credit include magnetically encoding the information on the card. This scheme is generally insecure. For example, it is not uncommon for credit card thieves to magnetically scan a credit card and simply steal the codes and use that code later. In accordance with the present invention, it will be almost impossible to design a reader to sense the codes without knowing the z-axis resistance signature of each of the zones. In addition, by controlling the ink compositions, printing or creating fake credit cards becomes almost impossible. This is so, because any entity that has a legitimate batch of credit card numbers would need to print those credit cards so that the proper codes having the unique z-axis resistance signatures and shape are provided on that card. However, without access to the inks and their unique compositions, and even assuming knowledge of the credit card numbers, would prevent a credit card thief from printing a batch of credit cards.

In a further embodiment, a magnetic potential material may be added so as to build a magnetic strip into the system. The magnetic potential material in combination with the z-axis ink provides a more robust layer of security. This desirably allows z-axis technology to be integrated onto cards or objects that currently use a magnetic strip to secure information, such as for example a credit card. This feature may be achieved by adding magnetite to the system or adding a z-axis resistive element or coating to a magnetic strip to make existing machines more secure. This augmentation of today's system may require only a slight modification, possibly software only, to read the layered magnetic fields in the z direction. In operation, the differences in magnetic fields at different layers as well as resistance and/or impedance would provide a signature along the z-axis at different layers.

As may be appreciated, in an embodiment specifically tailored to credit cards, credit card numbers may be placed on the cards using the various aspects of the present invention described above. The credit card numbers themselves may be created using unique z-axis resistive signatures as is shown, for example in FIG. 2D. In FIG. 2D, all of the information shown on the card would be printed using the z-axis unique signature of the present invention. Furthermore, since the z-axis resistance signatures are used to determine security, the signatures may be encoded at any location in the card and are not humanly visible. In a further variant on this embodiment, the credit shown in FIG. 2D may be made such that the security features are embedded in the card at a location not visible to the human eye or touch. For example, the z-axis system could be implemented in one or more of the numbers that are displayed, in the logo, the user's name, credit card company name, or any other location on the card. This is in contrast to present day systems where the security codes are embedded in a magnetic strip on the card.

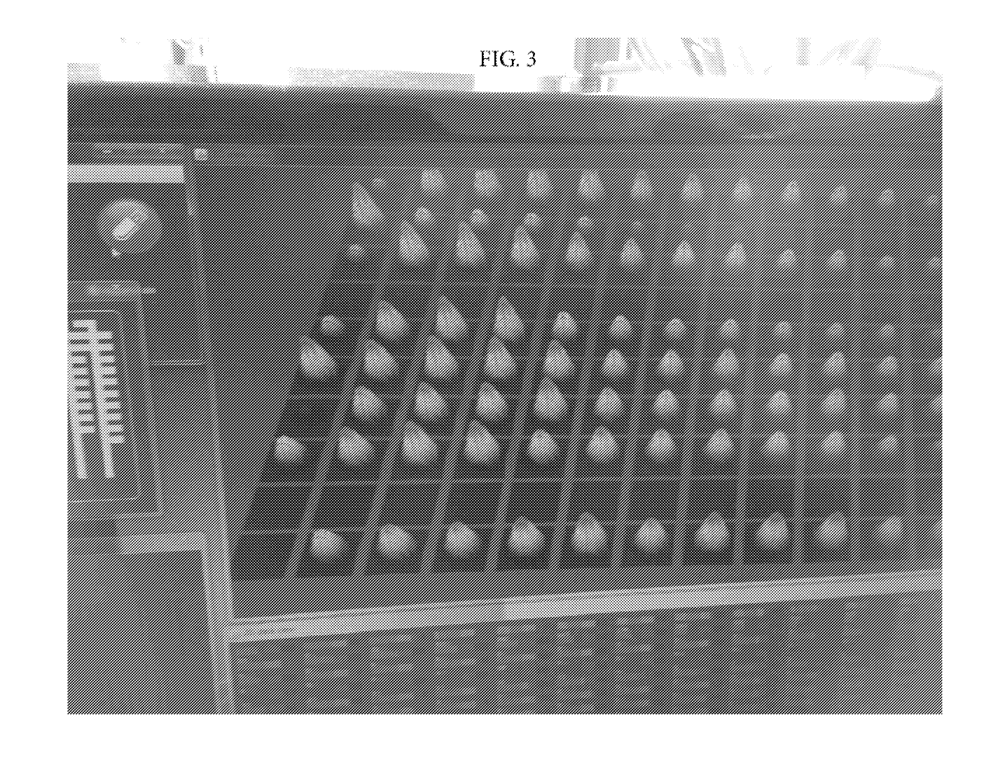

Turning now to FIG. 3, there is shown a resistance topography map of a plurality of sensing zones in accordance with an aspect of the present invention. Similar to FIG. 1A, the sensing zones are laid out on a grid-like structure. Along the y-direction is shown about ten sensing zones, while in the x-direction eleven zones are shown. Each sensing zone is shown using two or more colors. As will be appreciated, the different colors represent different resistant values. Further, different sensing zones show a different color topography, indicating different resistance values along the z-axis. For example, in FIG. 3, red represents one resistance value while yellow, blue and green represents different resistance values. Thus, along the z-axis, each grid shows different color patterns representing different resistances.

By modifying the shape or contouring the location of the sensing zones, information such as a credit card number, a company or user name, as shown in FIG. 2D, may be created on a card or other substrate. Further, it is also possible to create sensing zones with unique shapes and other characteristics that are not visible. That is, the ink that is used to create the sensing zones may be chosen so as to match the color of the background of the substrate. This provides yet another dimension to security that makes it even harder to detect a code, or much less replicate it.

Although the above description is provided with reference to a credit card, the zones are easily transportable to an application such as security for a currency or money, or any other form of a securable note. The substrate in this case would comprise the paper on which the currency or note is printed. The various inks that are applied to that paper to denote the value of the currency or note, are selected and laid out using the sensing zone concept disclosed in FIG. 1A. As one example, the face of Benjamin Franklin on a $100 bill could be encoded with sensing zones using a z-axis ink. Those sensing zones as discussed above could be created so that the shape of the zone and the resistance value along the z-axis of the individual subzones create a unique signature. Thus, the bill would have multiple levels of security including the z-axis resistance signatures, the footprint of the sensing zones, and the location of the sensing zones.

More generally, each letter in a person's name could have a different resistance. Further, since each letter has a different resistance the overall resistance of all the letters could thereby equal a unique resistance. With exact duplicates of names, any of the letters can be varied in point size, depth, added notations, etc. to give unique resistance signatures. Also, the background art could have a portion of it or one of the colors in the art be a z-axis or resistive print giving a unique signature to a card or currency. For example, if a picture of the credit card holder was on a card, one of the colors could be conductive and that picture would have its own unique resistance where the resistor looks like a part of the card but is not in a trace or linear shape.

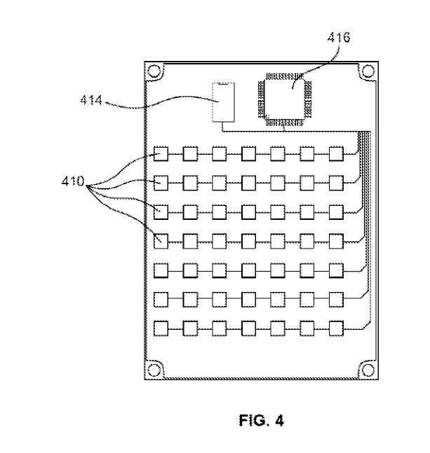

Turning now to FIG. 4, there is shown a reader in accordance with an additional aspect of the present invention. As is shown, the reader 400 includes a plurality of sensing elements 410 laid out in a grid. The reader also includes a number of electronic components 414, 416 that are arranged relative to the grid so that they may receive and process signals that are read by the grid 410. The electronic components preferably include one or more resistors, capacitors, trace lines, etc. and one or more processors and associated memory that are used in reading the z-axis resistance of an object that has been implemented in accordance with the above embodiments. The discrete components such as the resistors, capacitors and the like are selected so as to provide the proper signals to and from the grid 410 (and the individual elements making up the grid) to allow the processor element 416 to process the signature signals it receives. In one embodiment, the processor upon receipt of the signals from grid 410 compares the signals it receives a signature stored in a memory associated with a processor. If signals match the footprint and/or z-axis topography, then the card or object is acknowledged as authentic. If not, then the object or card is rejected.

In another embodiment, the signal sensed by the elements 410 on reader 400 may be sent over a network for further processing. In such a system, the reader 400 may include all the elements shown in FIG. 4. Alternatively, the reader may be less complicated such that the reader 400 functions as a relay without all the processing power needed to make the comparison. This simpler functioning may not warrant a full-blown processor, for example, but may be carried out using perhaps an application specific circuit chip or special purpose controller. It is also possible to carry out this functionality using a more sophisticated processor such as the type mentioned above, but without the additional coding, software or instructions needed to operate processor.

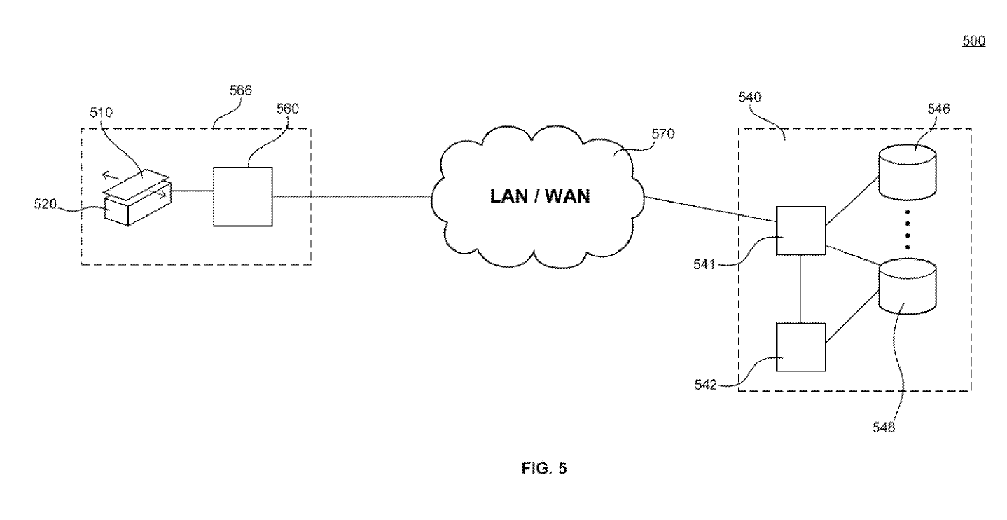

In accordance with a further aspect of the present invention, FIG. 5 shows a system that uses a z-axis signature as part of a shopping experience. In the system 500, an object 510, such as a credit card, is encoded with a uniques z-axis signature. The object 510 is made to interact with a reader 520. The interaction may comprise placing the object 510 proximate the reader 520 such that reader 520 senses the z-axis signature of the object. Such sensing may preferably occur due to interaction of the electric fields on the card and on the reader. In an embodiment where the z-axis conductive trace is on a dielectric substrate, the interaction with the reader operates to form a capacitive switch, if the reader itself provides a dielectric surface. In such an embodiment, the reader may comprise a cell phone that has the appropriate software such that when the screen of the cell phone interacts with the object, the resistance in the z-direction is read to determine the different resistance layers on the object.

Regardless of the form of the reader 520, once a reading is made of the z-axis signature on the object, the signals associated with the reading are sent from the reader 520 to one or more computers 541, 542 at a remote location 540. These computers 541, 542 are communicatively coupled to one or more databases 546, 548 that store the signatures associated with coded objects that are read by reader 520. In the case of a credit card, for example, the object 510 might be associated with a particular batch that has unique signature as discussed above. The computers 541, 542, individually or in some combined fashion, access the database to determine whether the signature reader 520 can be properly authenticated. If authenticated, the transaction involved in reading the card 510 is then allowed. If not, the transaction is rejected.

The system 500 may thus be implemented at a point-of-purchase (“POS”) in a retail transaction. In that regard, the reader 520 may also be coupled to an in-store computer 560, that is coupled to a local-area or wide-area network (or combination thereof) 570, that provides a connection to remote location 540. The object 510, reader 520 and computer 560 are thus located in a store 566 that is coupled to one or more servers 541, 542 of a credit card provider. In an embodiment the in-store computer 560 preferably communicates with credit card servers at location 540.

In view of the foregoing, an aspect of the present invention is an article of manufacture. The article preferably comprises a substrate having x, y and z-axes associate therewith, wherein the z-axis is perpendicular to the x and y-axes, and the x and y-axes are perpendicular to each other, and the z-axis be also perpendicular to a plane formed by a surface of the substrate. In a further aspect of the present invention, the axes are not limited to being perpendicular to each other, e.g., at 90 degree angles. The inks can be applied so that they are stepped with various angles so that the axes are not perpendicular to each other. In addition, it is also possible to halftone the inks of different resistances so one dot can reside next to another dot on the same plane.

The article further preferably comprises the first layer of conductive ink having a first resistance applied to the surface of the substrate, and the second layer of conductivity having a second resistance applied to a portion of the first layer of conductive ink, and an interface layer formed between the first and second layers. The interface layer preferably has a resistance profile that is formed from the predetermined combination of the first and second resistance layers such that the resistance profile includes varying resistance values along the z-axis.

In a preferred embodiment, the article of manufacture may include a substrate that is formed on or as the surface of a credit card, paper, clothing, toys, or any other object onto which a conductive ink may be applied or adhered to in some manner.

In accordance with further aspects of the present invention, additional layers of conductive ink may be applied to the second layer to form a multi-layer structure having multiple interfaces between the different conductive layers. Each interface may be designed so that there is a unique profile to the interface. Further, the different resistance values among all the layers along the z-axis direction creates a resistance signature that may be unique to the arrangement of resistance values.

In another aspect, the present invention includes a reader that interacts with the article of manufacture such that the resistance profile of the various layers of conductive inks and interfaces can be read and provided to a system that can authenticate the object or article of manufacture to which the conductive inks or traces have been applied. The reader preferably includes a plurality of sensors that are arranged so as to detect the resistance profile across a surface area of the object or article of manufacture. Accordingly, in a further embodiment, the resistance profile created by each arrangement of conductive layers create sensing zones. The sensing zones are preferably organized in a grid-like structure, which may be formed to create different footprints. Those footprints may include numbers, letters or any other indicia that may be created on an object using conductive inks or traces.

In yet another embodiment, the reader may be designed so as to have a split electrode that can read or alternately read at certain depths along the z-direction in order to accurately read layers of inks of the known dry film weight. Thus, the weight of the inks may be used to provide an additional layer of security that only a properly programmed reader will be able to detect.

Further, in accordance with an additional aspect of the present invention, cold or hot stamped foils, cold or hot transfer conductors, as well as different conductive molding layers that can be read in the z-axis direction for authentication and security reading may be employed in accordance with the various aspects of the present invention described above.

Further, the present invention may be applied so as to provide a surface that can be soldered to and read only in the z-direction thereby allowing for a very close access points. In this regard, providing a z-axis ink allows for actively reading the z-axis signatures by, for example, soldering an electrode. As the surface areas that accessible to actively access signals from a surface gets smaller, it has become more difficult to attach solder pads to such areas. By providing a z-axis resistance the solderable connection area effectively reduces to a dot, which may serve as solder point. This would avoid a potential problem of having a solder create a short because the surface area of connection extends in the x and y direction, and thus touches a neighboring solder point.

In accordance with a further aspect of the present invention, different dot shapes are possible. The dot, for example, includes the shape of the elements 10 in FIG. 1. Also, different dot gains may be implemented so that the layers are designed to get intentionally larger when printed by various techniques. In another aspect, one may go to different depths on the same print by adjusting the dot size and ink deposit. Further, various portions of a print can have more deposition then another portion such as in an offset keyline. This would look like stripes in the same color that nobody visibly could pick up but one inch apart, there could be densities for example of 1.2 and one inch away it could be a 1.9 density of the same color. The bcm (billion cubic microns per square inch) on a flexo anilox could also be adjusted to vary in depth so the ink deposit would vary according to a multi bcm anilox roll.

Although the invention herein has been described with reference to particular embodiments, it is to be understood that these embodiments are merely illustrative of the principles and applications of the present invention. It is therefore to be understood that numerous modifications will be made to be illustrative embodiments and that other embodiments that may be devised without departing from the spirit and scope of the present invention.

1. An article of manufacture, comprising:
a substrate having x, y and z-axes associated therewith, wherein the z-axis is perpendicular to the x and y-axes, and the x and y-axes are perpendicular to each other;
the z-axis being perpendicular to a plane formed by a surface of the substrate;
a first layer of conductive ink having a first resistance applied to the surface of the substrate;
a second layer of conductive ink having a second resistance applied to a portion of the first layer of the conductive ink; and
an interface layer formed between the first layer and second layer, the interface layer having a resistance profile formed from a predetermined combination of the first and second resistance layers such that the resistance profile includes varying resistance values along the z-axis.
